(19) United States
(12) Patent Application Publication
(10) Pub. No.: US 2026/0083000 A1
(43) Pub. Date: Mar. 19, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Yi-Min FU, Taichung City (TW); Chi-Ching HO, Taichung City (TW); Yu-Po WANG, Taichung City (TW)

(73) Assignee: SILICONWARE PRECISION INDUSTRIES CO., LTD., Taichung City (TW)

(21) Appl. No.: 19/018,508

(22) Filed: Jan. 13, 2025

(30) Foreign Application Priority Data
Sep. 16, 2024 (TW) 113135116

(51) Int. Cl. H01L 25/16; G02B 6/42; G02B 6/43; H01L 21/3105; H01L 21/56; H01L 23/00; H01L 23/31; H01L 23/538; H05K 1/18

(52) U.S. Cl. CPC H10W 90/00; G02B 6/428; G02B 6/43; H10P 95/06; H10W 70/611; H10W 70/65; H10W 70/685; H10W 74/012; H10W 74/114; H10W 74/15; H05K 1/181; H10W 74/10; H10W 90/401; H10W 90/724; H10W 90/734

(57) ABSTRACT

An electronic package and a manufacturing method thereof are provided. The electronic package includes a carrier structure, an electronic element, a bridge element, an encapsulation layer, and a photonic element. The electronic element and the bridge element are disposed on a second surface of the carrier structure to be electrically connected to the carrier structure. The encapsulation layer covers the electronic element and the bridge element. The photonic element is disposed on a surface of the encapsulation layer and is electrically connected to the bridge element. In the electronic package and the manufacturing method thereof, the photonic element is disposed after the formation and grinding of the encapsulation layer are completed, the photonic element can be prevented from covering by the encapsulation, thereby contamination or damage to the light transmitters and the light receivers of the photonic element can be avoided.

### BACKGROUND

### 1. Technical Field

The present disclosure relates to a package structure, and more particularly, to an electronic package and a manufacturing method thereof.

### 2. Description of Related Art

With the increasing requirements for data network bandwidth, shortcomings such as signal attenuation and crosstalk caused by radiation of electromagnetic energy in traditional copper data channels have gradually emerged, optical communication has been regarded as the successor of copper links. Especially in the 21st century, technological advancements such as post-PC era, mobile communications, and artificial intelligence have driven changes in life culture such as mobile internet access, online shopping, video streaming, and online games. Copper cables are insufficient for use in the increasing bandwidth requirements stimulated by the above.

In addition, high performance computing (HPC) technology becomes more important and is widely used in present life, such as medical technology development of cancer drug development, or automatic sensing detection computing of self-driving cars. In order to be applied in the aforementioned technology fields, the traffic of data center is also increased.

To increase the bandwidth of data network and solve the demand pressure of data center, silicon photonic solutions that combine various advanced packaging technologies have been developed accordingly.

At present, optical communication within data center mainly relies on pluggable devices as optical fiber connection interfaces to achieve photoelectric conversion or electro-optical conversion between the transmitter and the receiver. In the internal architecture of data center, all switches, routers, and nodes basically need to be equipped with pluggable devices. As for large data center, the number of pluggable devices required to be deployed is very large, which brings a relatively heavy burden and increases transmission delay and power consumption. More importantly, if the future transmission rate requirements reach 1.6 Tb/s, 3.2 Tb/s, or even higher transmission rates, pluggable devices are also limited by performances. Therefore, how to use optical communication principles and how to change package structure to increase transmission bandwidth are actually urgent problems that need to be solved in the industry.

### SUMMARY

In view of the aforementioned shortcomings of the prior art, the present disclosure provides an electronic package, which includes a carrier structure, an electronic element, a bridge element, an encapsulation layer and a photonic element. The carrier structure has a first surface and a second surface opposite to the first surface. The electronic element is disposed on the second surface of the carrier structure to be electrically connected to the carrier structure. The bridge element is disposed on the second surface of the carrier structure to be electrically connected to the carrier structure. The encapsulation layer covers the electronic element and the bridge element. The photonic element is disposed on a surface of the encapsulation layer and is electrically connected to the bridge element.

The present disclosure further provides a method of manufacturing an electronic package, which includes: placing a carrier structure on a carrier, wherein the carrier structure has a first surface and a second surface opposite to the first surface; disposing an electronic element on the second surface of the carrier structure to be electrically connected to the carrier structure; disposing a bridge element on the second surface of the carrier structure to be electrically connected to the carrier structure; forming an encapsulation layer to cover the electronic element and the bridge element; and disposing a photonic element on a surface of the encapsulation layer to be electrically connected to the bridge element.

In the electronic package and method thereof of the present disclosure, the photonic element is disposed after completion of the formation and grinding of the encapsulation layer, to prevent the encapsulation layer from covering the photonic element, and thus contamination or damage to the light transmitters and the light receivers of the photonic element can be avoided.

### BRIEF DESCRIPTION OF THE DRAWINGS

FIG. 1 to FIG. 6 are schematic cross-sectional views showing an electronic package and manufacturing method thereof of the present disclosure.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “under,” “a,” “first,” “second,” and the like are merely used for clear explanation rather than limiting the practicable scope of the present disclosure, and thus, alterations or adjustments of the relative relationships thereof without essentially altering the technical contents should still be considered in the practicable scope of the present disclosure.

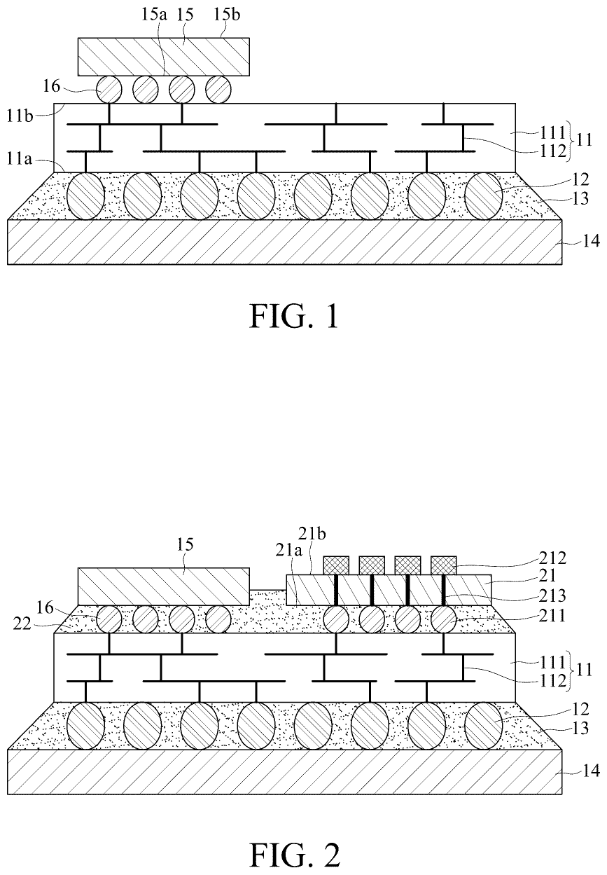

FIG. 1 to FIG. 6 are schematic cross-sectional views showing an embodiment of a method of manufacturing an electronic package of the present disclosure.

First, as shown in FIG. 1, a carrier structure 11 is placed on a carrier 14. In specific, the carrier structure 11 has a first surface 11a and a second surface 11b opposite to the first surface 11a, a plurality of conductors 12 are disposed on the first surface 11a, each of the conductors 12 is, for example, a conductive pillar, or a conductive bump, and the carrier structure 11 is placed on the carrier 14 through the conductors 12 and an adhesive 13.

The carrier structure 11 may be a package substrate, an interposer, or a circuit structure, which includes at least one insulating layer 111 and at least one circuit layer 112 bonded to the at least one insulating layer 111. For example, a material forming the circuit layer 112 is copper, and a material forming the insulating layer 111 may be poly(p-phenylene-2,6-benzobisoxazole) (PBO), polyimide (PI), prepreg (PP), or other dielectric material.

Due to requirements of reducing line width, line spacing, and thickness in product applications, the carrier structure 11 may be a package substrate, an interposer, or a circuit structure in a coreless form.

Besides, the electronic element 15 is disposed on the second surface 11b of the carrier structure 11 to be electrically connected to the carrier structure 11.

The electronic element 15 may be an active element, a passive element, or a combination thereof. The active element is, for example, a semiconductor chip, and the passive element is, for example, a resistor, a capacitor, and an inductor.

The electronic element 15 has an active surface 15a and an inactive surface 15b opposite to the active surface 15a, and the electronic element 15 is bonded to the second surface 11b of the carrier structure 11 through a plurality of first conductive elements 16 in a flip-chip manner to be electrically connected to the carrier structure 11. Each of the first conductive elements 16 may be made of a solder material or a conductive metal material.

As shown in FIG. 2, the bridge element 21 is disposed on the second surface 11b of the carrier structure 11 to be electrically connected to the carrier structure 11.

In specific, the bridge element 21 may be an interposer or other circuit structure. The bridge element 21 has a first surface 21a and a second surface 21b opposite to the first surface 21a, and the bridge element 21 includes a plurality of second conductive elements 211 disposed on the first surface 21a, a plurality of conductive contacts 212 disposed on the second surface 21b, and a plurality of conductive vias 213 disposed inside the bridge element 21. The plurality of conductive vias 213 are electrically connected to the plurality of second conductive elements 211 and the plurality of conductive contacts 212.

Each of the second conductive elements 211 may be formed of a solder material or a conductive metal material. Each of the conductive contacts 212 and each of the conductive vias 213 may be made of copper of other conductive material.

Subsequently, the plurality of first conductive elements 16 and the plurality of second conductive elements 211 are covered by a first underfill 22.

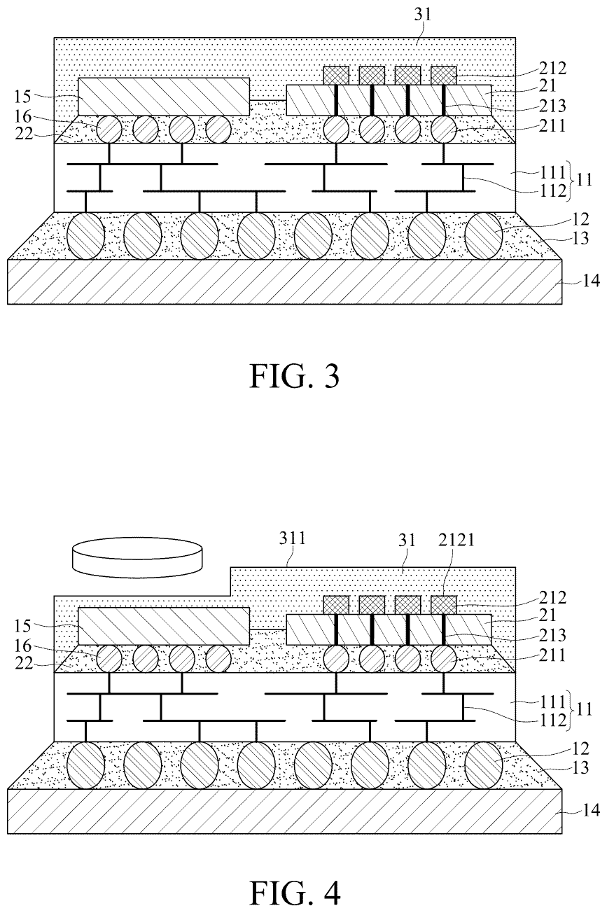

As shown in FIG. 3, an encapsulation layer 31 is formed on the carrier structure 11 to cover the electronic element 15 and the bridge element 21. A material forming the encapsulation layer is an insulating material, such as polyimide (PI) or epoxy resin packaging compound or packaging material. The encapsulation layer 31 may be formed by molding, lamination, or coating.

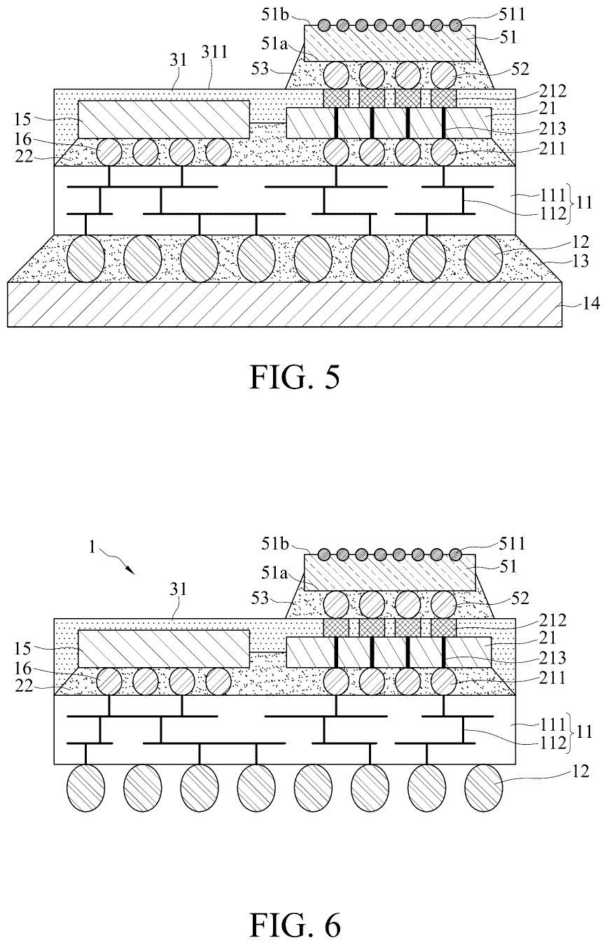

As shown in FIG. 4, the encapsulation layer 31 is grinded, and a surface of the encapsulation layer 31 (e.g., an upper surface 311 shown in FIG. 4 and FIG. 5) is aligned with a surface of each of the conductive contacts 212 (e.g., the upper surface 2121 shown in FIG. 4) to expose the plurality of conductive contacts 212.

As shown in FIG. 5, a photonic element 51 is disposed on a surface of the encapsulation layer 31 (e.g., the upper surface 311) to be electrically connected to the bridge element 21. For example, the photonic element 51 may be a light emitting die (LED).

The photonic element 51 has a first surface 51a and a second surface 51b opposite to the first surface 51a, the photonic element 51 is electrically connected to the bridge element 21 through the first surface 51a and a plurality of third conductive elements 52, and a plurality of light transmitters/light receivers 511 are disposed on the second surface 51b. In other words, each element 511 can be a light transmitter or a light receiver.

Each of the third conductive elements 52 may be formed of solder material, or a conductive metal material. The plurality of light transmitters/light receivers 511 may be a transmitting end and a receiving end of the photonic element 51, respectively.

Furthermore, a second underfill 53 can be used to cover the plurality of third conductive elements 52.

As shown in FIG. 6, removing the adhesive 13 and the carrier 14 to complete the electronic package 1.

The electronic package 1 includes the conductors 12, the carrier structure 11, the electronic element 15, the first conductive elements 16, the bridge element 21, the second conductive elements 211, the first underfill 22, the encapsulation layer 31, the photonic element 51, the third conductive elements 52, and the second underfill 53.

The bridge element 21 is electrically connected to the circuit layer 112 of the carrier structure 11 through the plurality of second conductive elements 211, and the bridge element 21 is electrically connected to the photonic element 51 through the plurality of conductive contacts 212 and the plurality of third conductive elements 52. The circuit layer 212 of the carrier structure 11 is electrically connected to the electronic element 15, the bridge element 21, and the plurality of conductors 12. Therefore, the plurality of conductors 12 are electrically connected to the electronic element 15 through the circuit layer 112 of the carrier structure 11 and the first conductive element 16, and the plurality of conductors 12 is electrically connected to the photonic element 51 through the circuit layer 112 of the carrier structure 11, the bridge element 21, and the third conductive element 52.

Since the plurality of light transmitters/light receivers 511 are disposed on the photonic element 51, the light transmitters/light receivers 511 cannot be contaminated or damaged, and thus the bridge element 21 is disposed between the carrier structure 11 and the photonic element 51, allowing the photonic element 51 to be disposed above the encapsulation layer 31 without being covered by the encapsulation layer 31 to avoid contamination or damage to the light transmitters/light receivers 511. In contrast, if the photonic element 51 is directly disposed on the carrier structure 11 and then molding is performed, the encapsulation layer 31 will cover the light transmitters/light receivers 511 that will be damaged after grinding the encapsulation layer 31 for removing the encapsulation layer 31 on the light transmitters/light receivers 511.

To sum up, in the electronic package 1 and the manufacturing method thereof of the present disclosure, the photonic element 51 is raised by the bridge element 21, the photonic element 51 is configured after completion of the formation and grinding of the encapsulation layer 31. Therefore, the photonic element 51 can be prevented from being covered by the encapsulation layer 31, thereby contamination or damage to light transmitters/light receivers 511 can be avoided. In addition, the electronic package 1 of the present disclosure can be manufactured using existing semiconductor packaging processes without developing special process or purchasing special equipment, and thus production costs can be reduced.

The above embodiments are disposed for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier structure having a first surface and a second surface opposite to the first surface;
an electronic element disposed on the second surface of the carrier structure to be electrically connected to the carrier structure;
a bridge element disposed on the second surface of the carrier structure to be electrically connected to the carrier structure;
an encapsulation layer formed on the second surface of the carrier structure to cover the electronic element and the bridge element; and
a photonic element disposed on a surface of the encapsulation layer and electrically connected to the bridge element.

2. The electronic package of claim 1, wherein the carrier structure is a package substrate, an interposer, or a circuit structure in a coreless form.

3. The electronic package of claim 1, further comprising:
a plurality of conductors disposed on the first surface of the carrier structure to be electrically connected to the electronic element through the carrier structure, and to be electrically connected to the photonic element through the carrier structure and the bridge element.

4. The electronic package of claim 3, wherein the carrier structure comprises at least one insulating layer and at least one circuit layer bonded to the at least one insulating layer, and the at least one circuit layer is electrically connected to the electronic element, the bridge element, and the plurality of conductors.

5. The electronic package of claim 1, wherein the electronic element has an active surface and an inactive surface opposite to the active surface, and the electronic element is bonded to the second surface of the carrier structure through a plurality of first conductive elements in a flip-chip manner to be electrically connected to the carrier structure.

6. The electronic package of claim 1, wherein the bridge element has a first surface and a second surface opposite to the first surface, a plurality of second conductive elements are disposed on the first surface of the bridge element, a plurality of conductive contacts are disposed on the second surface of the bridge element, a plurality of conductive vias are disposed in the bridge element, and the plurality of conductive vias are electrically connected to the plurality of second conductive elements and the plurality of conductive contacts.

7. The electronic package of claim 6, wherein the bridge element is electrically connected to the carrier structure through the plurality of second conductive elements and is electrically connected to the photonic element through the plurality of conductive contacts.

8. The electronic package of claim 6, wherein the surface of the encapsulation layer is aligned with a surface of each of the conductive contacts to expose the plurality of conductive contacts.

9. The electronic package of claim 1, wherein the photonic element has a first surface and a second surface opposite to the first surface, the photonic element is electrically connected to the bridge element through the first surface of the photonic element and a plurality of third conductive elements, and a plurality of light transmitters and a plurality of light receivers are disposed on the second surface of the photonic element.

10. A method of manufacturing an electronic package, comprising:
placing a carrier structure on a carrier, wherein the carrier structure has a first surface and a second surface opposite to the first surface;
disposing an electronic element on the second surface of the carrier structure to be electrically connected to the carrier structure;
disposing a bridge element on the second surface of the carrier structure to be electrically connected to the carrier structure;
forming an encapsulation layer on the second surface of the carrier structure to cover the electronic element and the bridge element; and
disposing a photonic element on a surface of the encapsulation layer to be electrically connected to the bridge element.

11. The method of claim 10, wherein the carrier structure is a package substrate, an interposer, or a circuit structure in a coreless form.

12. The method of claim 10, wherein a plurality of conductors are disposed on the first surface of the carrier structure, the plurality of conductors are electrically connected to the electronic element through the carrier structure, and are electrically connected to the photonic element through the carrier structure and the bridge element.

13. The method of claim 12, wherein the carrier structure comprises at least one insulating layer and at least one circuit layer bonded to the at least one insulating layer, and the at least one circuit layer is electrically connected to the electronic element, the bridge element, and the plurality of conductors.

14. The method of claim 10, wherein the electronic element has an active surface and an inactive surface opposite to the active surface, and the electronic element is bonded to the second surface of the carrier structure through a plurality of first conductive elements in a flip-chip manner to be electrically connected to the carrier structure.

15. The method of claim 10, wherein the bridge element has a first surface and a second surface opposite to the first surface, a plurality of second conductive elements are disposed on the first surface of the bridge element, a plurality of conductive contacts are disposed on the second surface of the bridge element, a plurality of conductive vias are disposed in the bridge element, and the plurality of conductive vias are electrically connected to the plurality of second conductive elements and the plurality of conductive contacts.

16. The method of claim 15, wherein the bridge element is electrically connected to the carrier structure through the plurality of second conductive elements and is electrically connected to the photonic element through the plurality of conductive contacts.

17. The method of claim 15, further comprising:
grinding the encapsulation layer, and thus the surface of the encapsulation layer is aligned with a surface of each of the conductive contacts to expose the plurality of conductive contacts.

18. The method of claim 10, wherein the photonic element has a first surface and a second surface opposite to the first surface, the photonic element is electrically connected to the bridge element through the first surface of the photonic element and a plurality of third conductive elements, and a plurality of light transmitters and a plurality of light receivers are disposed on the second surface of the photonic element.
